(19) United States
(12) Patent Application Publication
(10) Pub. No.: US 2016/0043336 A1
(43) Pub. Date: Feb. 11, 2016

(54) FLEXIBLE DISPLAY APPARATUS AND MANUFACTURING METHOD THEREOF

(71) Applicant: SAMSUNG DISPLAY CO., LTD., Yongin-City (KR)

(72) Inventors: Chiwoo KIM, Yongin-City (KR); Minhwan CHOI, Yongin-City (KR); Jeanyoung KANG, Yongin-City (KR); Kyunghan KIM, Yongin-City (KR); Kwansu KIM, Yongin-City (KR); Daewon PARK, Yongin-City (KR); Kyungjin YOO, Yongin-City (KR); Sangmin JANG, Yongin-City (KR); Myeongseok JEONG, Yongin-City (KR)

(21) Appl. No.: 14/705,183

(22) Filed: May 6, 2015

(30) Foreign Application Priority Data
Aug. 5, 2014 (KR) 10-2014-0100704

(51) Int. Cl. H01L 51/00; H01L 51/56; H01L 27/32

(52) U.S. Cl. CPC H01L 51/0097; H01L 27/323; H01L 27/3262; H01L 51/56; H01L 27/322

(57) ABSTRACT

A method of manufacturing a flexible display apparatus includes forming a first flexible substrate on a first sacrificial layer on a first support substrate, forming a display layer on the first flexible substrate, forming an encapsulation layer on the display layer, forming a second flexible substrate on a second sacrificial layer on a second support substrate, forming a touch screen layer on the second flexible substrate, forming a color filter layer on the touch screen layer, bonding the first support substrate and the second support substrate based on an adhesive layer between the encapsulation layer and the color filter layer, and detaching the first support substrate and the second support substrate by performing a delaminating operation between the first sacrificial layer and the first flexible substrate and between the second sacrificial layer and the second flexible substrate.

### CROSS-REFERENCE TO RELATED APPLICATION

Korean Patent Application No. 10-2014-0100704, filed on Aug. 5, 2014, and entitled, “Flexible Display Apparatus and Manufacturing Method Thereof,” is incorporated by reference herein in its entirety.

### BACKGROUND

1. Field

One or more embodiments described herein relate to a flexible display apparatus and a method for manufacturing a flexible display apparatus.

2. Description of the Related Art

Organic light-emitting displays have wide view angles, good contrast, and quick response speeds, and thus have been highlighted as a next-generation display apparatus.

An organic light-emitting display may have thin-film transistors and organic light-emitting devices formed on a substrate. The organic light-emitting devices are self-emitting devices that generate light for forming an image. Displays of this type have been used in portable electronic devices (e.g., mobile phones) and larger-sized products such as televisions and monitors.

### SUMMARY

In accordance with one embodiment, a method of manufacturing a flexible display apparatus includes forming a first flexible substrate on a first sacrificial layer on a first support substrate, forming, on the first flexible substrate, a display layer including a thin-film transistor and an organic light-emitting device electrically connected to the thin-film transistor, forming a thin-film encapsulation layer on the display layer by alternately stacking organic and inorganic layers, forming a second flexible substrate on a second sacrificial layer on a second support substrate, forming a touch screen layer on the second flexible substrate, forming, on the touch screen layer, a color filter layer including color filters and a light-blocking layer between adjacent ones of the color filters, bonding the first support substrate and the second support substrate based on an adhesive layer between the thin-film encapsulation layer and the color filter layer, and detaching the first support substrate and the second support substrate by performing a delaminating operation between the first sacrificial layer and the first flexible substrate and between the second sacrificial layer and the second flexible substrate. Each of the first flexible substrate and the second flexible substrate may include a metallic material or a plastic material. Detaching the first support substrate and detaching the second support substrate may be performed using a laser beam.

In accordance with another embodiment, a method of manufacturing a flexible display apparatus includes forming a first flexible substrate on a first sacrificial layer on a first support substrate, forming. on the first flexible substrate, a display layer including a thin-film transistor and an organic light-emitting device electrically connected to the thin-film transistor, forming a thin-film encapsulation layer on the display layer by alternately stacking organic and inorganic layers, forming, on a second sacrificial layer on a second support substrate, an upper panel unit including a second flexible substrate, a touch screen layer on the second flexible substrate, and a color filter layer including color filters and a light-blocking layer between adjacent ones of the color filters on the touch screen layer, detaching the upper panel unit from the second support substrate by performing a delaminating between the second sacrificial layer and the upper panel unit, bonding the first support substrate and the upper panel unit based on an adhesive layer between the thin-film encapsulation layer and the upper panel unit, and detaching the first support substrate by performing a delaminating operation between the first sacrificial layer and the first flexible substrate. Each of the first flexible substrate and the second flexible substrate may include a metallic material or a plastic material. Detaching the first support substrate and detaching the second support substrate may be performed using a laser beam.

In accordance with another embodiment, a method of manufacturing a flexible display apparatus includes forming a lower panel unit by forming a first flexible substrate on a first sacrificial layer on a first support substrate, forming, on the first flexible substrate, a display layer including a thin-film transistor and an organic light-emitting device electrically connected to the thin-film transistor, and forming a thin-film encapsulation layer on the display layer by alternately stacking organic and inorganic layers, detaching the lower panel unit from the first support substrate by performing a delaminating operation between the first sacrificial layer and the first flexible substrate, forming a second flexible substrate on a second sacrificial layer on a second support substrate, forming a touch screen layer on the second flexible substrate, forming, on the touch screen layer, a color filter layer including color filters and a light-blocking layer disposed between adjacent ones of the color filters, bonding the lower panel unit and the second support substrate based on an adhesive layer between the thin-film encapsulation layer and the color filter layer, and detaching the second support substrate by performing a delaminating operation between the second sacrificial layer and the second flexible substrate. Each of the first flexible substrate and the second flexible substrate may include a metallic material or a plastic material. Detaching the first support substrate and detaching the second support substrate may be performed using a laser beam.

In accordance with another embodiment, a flexible display apparatus includes a first flexible substrate, a display layer on the first flexible substrate and including an organic light-emitting device electrically connected to a thin-film transistor, a thin-film encapsulation layer on the display layer and including a stack of alternating organic and inorganic layers, a color filter layer on the thin-film encapsulation layer and including color filters and a light-blocking layer between adjacent ones of the color filters, a touch screen layer on the color filter layer, a second flexible substrate on the touch screen layer, and an adhesive layer between the thin-film encapsulation layer and the color filter layer. The color filter layer, the touch screen layer, and the second flexible substrate may be in one body. Each of the first flexible substrate and the second flexible substrate may include a metal or a plastic material.

In accordance with another embodiment, a method of manufacturing a flexible display apparatus includes forming a touch screen layer and a color filter layer on a first flexible substrate as one body, the first flexible substrate on a support layer, detaching the one body from the support layer, and bonding the one body to an encapsulation layer.

A sacrificial layer may be between the one body and the support layer before the one body is detached from the support layer. The first flexible substrate may include a metallic material or a plastic material. The encapsulation layer may include a stack of alternating organic and inorganic layers.

Forming the color filter layer may include forming the color filter on the touch screen layer, the color filter layer including a plurality of color filters and a light-blocking layer between adjacent ones of the color filters.

The method may include Forming a display layer on a second flexible substrate, the display layer including an organic light-emitting device electrically connected to a transistor, forming the thin-film encapsulation layer on the display layer, and bonding the encapsulation layer to the color filter layer. The encapsulation layer may be bonded to the color filter layer by an adhesive layer. A sacrificial layer may be between the second flexible substrate and the display layer.

### BRIEF DESCRIPTION OF THE DRAWINGS

Features will become apparent to those of skill in the art by describing in detail exemplary embodiments with reference to the attached drawings in which:

FIGS. 1A to 3 illustrate an embodiment of a method for manufacturing a flexible display apparatus;

FIGS. 4A to 6 illustrate another embodiment of a method for manufacturing a flexible display apparatus;

FIGS. 7A to 9 illustrate another embodiment of a method for manufacturing a flexible display apparatus; and

FIG. 10 illustrates an embodiment of a flexible display apparatus.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

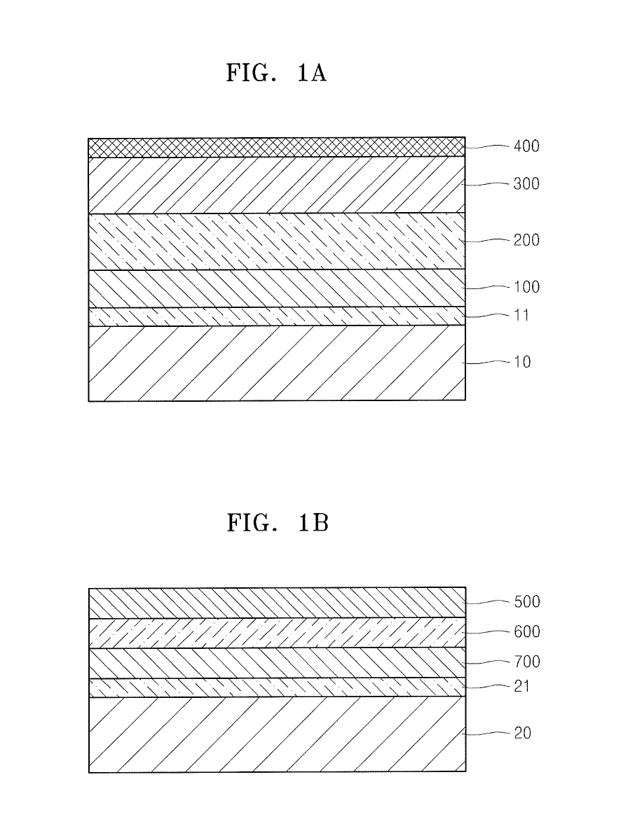

FIGS. 1A to 3 are cross-sectional views illustrating an embodiment of a method for manufacturing a flexible display apparatus.

Referring to FIG. 1A, a first flexible substrate 100 is formed on a first sacrificial layer 11 on a first support substrate 10. The first support substrate 10 may include a glass material, a metallic material, and/or other materials having a predetermined degree of solidness. The first flexible substrate 100 has a flexible characteristic, and the first support substrate 10 supports the first flexible substrate 100 and one or more additional layers.

The first sacrificial layer 11 may be first formed on the first support substrate 10 before forming the first flexible substrate 100. The first sacrificial layer 11 may include, for example, amorphous silicon (a-Si), a metallic material, an organic material such as polyimide. and/or other various materials. The first sacrificial layer 11 may protect the first flexible substrate 100, and may allow detachment of the first flexible substrate 100 from the first support substrate 10 to be easily performed.

The first flexible substrate 100 has a flexible characteristic and may be formed. for example. of a metallic material, a plastic material (such as polyethylene terephthalate (PET), polyethylene naphthalate (PEN), polyimide), and/or various other materials. In one embodiment, a thin metal foil such as steel use stainless (SUS) may be used.

Thereafter, a display layer 200 may be formed on the first flexible substrate 100.

The display layer 200 may include, for example, a thin-film transistor (TFT), a capacitor CAP, and an organic light-emitting device electrically connected to the TFT. The organic light-emitting device may have a predetermined number of sub-pixels, e.g., red (R), green (G), blue (B) sub-pixels and/or another combination of colors or white.

A thin-film encapsulation layer 300 is formed on the display layer 200. The thin-film encapsulation layer 300 may be formed, for example, by alternately stacking inorganic and organic layers. Because the organic light-emitting device is formed of an organic material, the organic light-emitting device may be weak in oxygen, humidity, and/or other external or environmental conditions. Thus, the thin-film encapsulation layer 300 may be formed to have a multi-layer structure on the organic light-emitting device, in order to protect the organic light-emitting device from these conditions (e.g., oxygen and/or humidity permeated from the outside).

An adhesive layer 400 may be formed on the thin-film encapsulation layer 300. The adhesive layer 400 functions to bond a color filter layer 500 and the thin-film encapsulation layer 300. FIG. 1A illustrates that the adhesive layer 400 is formed on the thin-film encapsulation layer 300. In another embodiment, the adhesive layer 400 may be formed on the color filter layer 500. The adhesive layer 400 may be formed of silicon or another material.

Referring to FIG. 1B, a second flexible substrate 700 is formed on a second sacrificial layer 21 on a second support substrate 20. The second support substrate 20 may include a glass material, a metallic material, and/or other materials having a predetermined solidness. The second flexible substrate 700 has a flexible characteristic, and the second support substrate 20 supports the second flexible substrate 700 and one or more additional layers.

The second sacrificial layer 21 may be first formed on the second support substrate 20 before forming the second flexible substrate 700. The second sacrificial layer 21 may include a-Si, a metallic material, an organic material such as polyimide, and/or other materials. The second sacrificial layer 21 may protect the second flexible substrate 700 and allow detachment of the second flexible substrate 700 from the second support substrate 20 to be easily performed.

The second flexible substrate 700 may have the same flexible characteristic as the first flexible substrate 100, and may be formed of a metallic material, a plastic material such as PET, PEN, polyimide, and/or other materials. In one embodiment, a thin metal foil such as SUS may be used.

Thereafter, a touch screen layer 600 may be formed on the second flexible substrate 700. The touch screen layer 600 may include a touch sensor. The touch sensor may include a first electrode and a second electrode which are alternately disposed and which have a hexagonal shape, diamond shape, or other shape. The touch sensor may be a capacitive touch sensor, e.g., one in which a touch is determined by detecting a change in capacitance among one or more of a plurality of first electrodes and second electrodes.

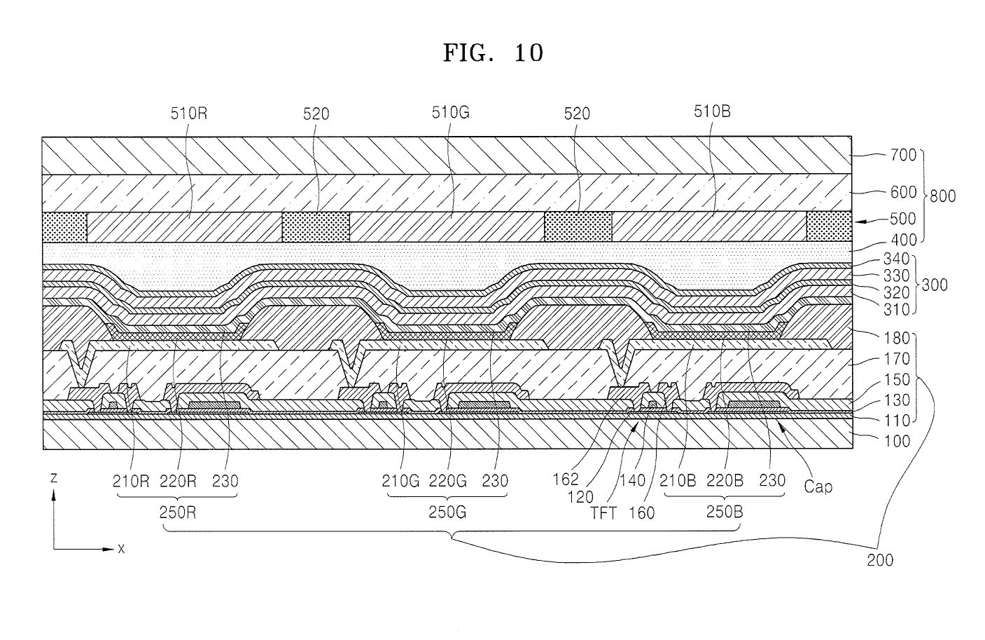

The color filter layer 500 may be formed on the touch screen layer 600. The color filter layer 500 may include, for example, color filters 510R, 510G, and 510B (refer to FIG. 10). A light-blocking layer 520 (refer to FIG. 10) may be between the color filters 510R, 510G, and 510B. The color filters 510R, 510G, and 510B are formed for the sub-pixels of R, G, and B, respectively. The light-blocking layer 520 may be formed between the color filters 510R, 510G, and 510B formed for the respective sub-pixels, in order to prevent light emitted by the sub-pixels of R, G, and B from leaking to an adjacent sub-pixel.

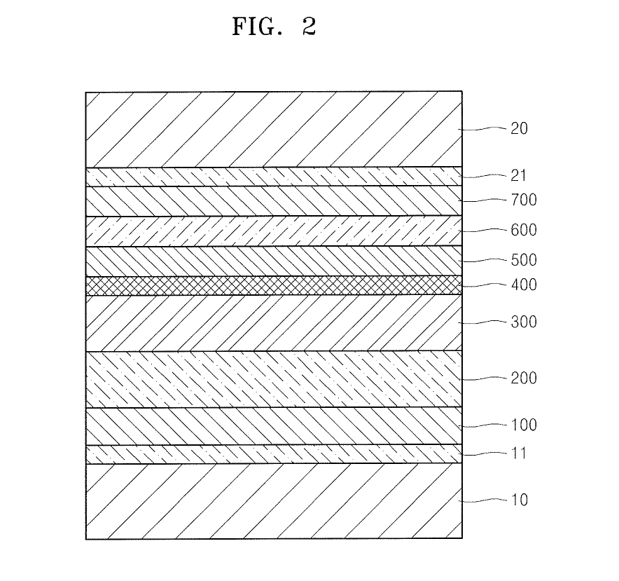

Thereafter, referring to FIG. 2, the first support substrate 10 and the second support substrate 20 may be bonded by an adhesive layer 400 between the thin-film encapsulation layer 300 and the color filter layer 500. For example, as shown in FIG. 2, the second support substrate 20 is bonded to the first support substrate 10, so as to face the first support substrate 10. As a result, the following layers are sequentially arranged: the first flexible substrate 100, the display layer 200, the thin-film encapsulation layer 300, the adhesive layer 400, the color filter layer 500, the touch screen layer 600, the second flexible substrate 700, and the second support substrate 20 from the first support substrate 10. In one embodiment, the second sacrificial layer 21 may be between the second flexible substrate 700 and the second support substrate.

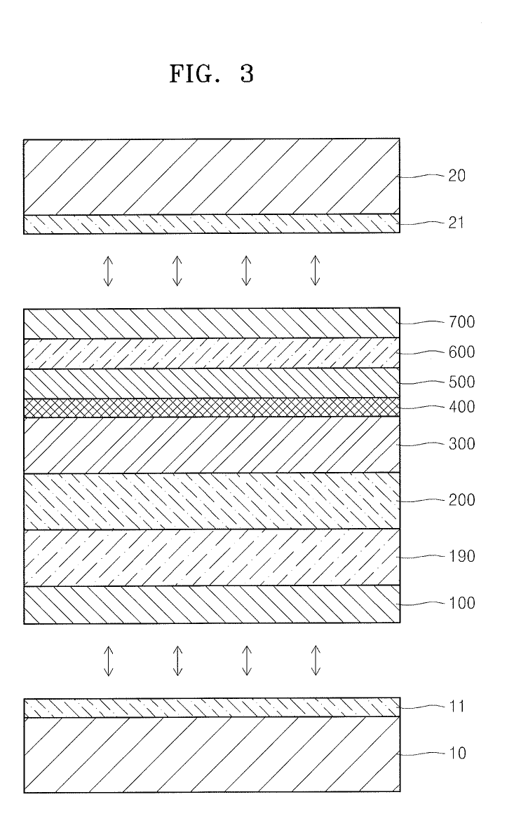

Thereafter, referring to FIG. 3, the first support substrate 10 may be detached by performing a delaminating operation between the first sacrificial layer 11 and the first flexible substrate 100. Likewise, the second support substrate 20 may be detached by performing a delaminating operation between the second sacrificial layer 21 and the second flexible substrate 700.

When the first sacrificial layer 11 and the second sacrificial layer 21 include a-Si, the first support substrate 10 and the second support substrate 20 may be detached, for example, by irradiating a laser beam thereon. The laser may be, for example, an excimer laser, a solid-state laser, or a pulse laser. Other methods of detachment may be used, for example, depending on materials of the first sacrificial layer 11 and the second sacrificial layer 21.

After detaching the first support substrate 10 and the second support substrate 20, a protective film may be attached to the surfaces of the first flexible substrate 100 and the second flexible substrate 700. The protective film may protect the first flexible substrate 100 and the second flexible substrate 700 from an external impact, impurities, and the like.

The present method embodiment, therefore, includes a process of forming the touch screen layer 600 and the color filter layer 500 on the second flexible substrate 700 as one body, detaching the one body from the second support layer 20, and bonding the one body to the thin-film encapsulation layer 300. As a result, light-extraction efficiency may be improved through the color filters 510R, 510G, and 510B that correspond to respective sub-pixels without using a polarizer. Also, a touch screen panel (TSP) may be simultaneously formed through the touch screen layer 600. and may be formed in one body with the color filter layer 500, without a separate module process. Thus. the total process may be simplified and manufacturing costs may be significantly reduced.

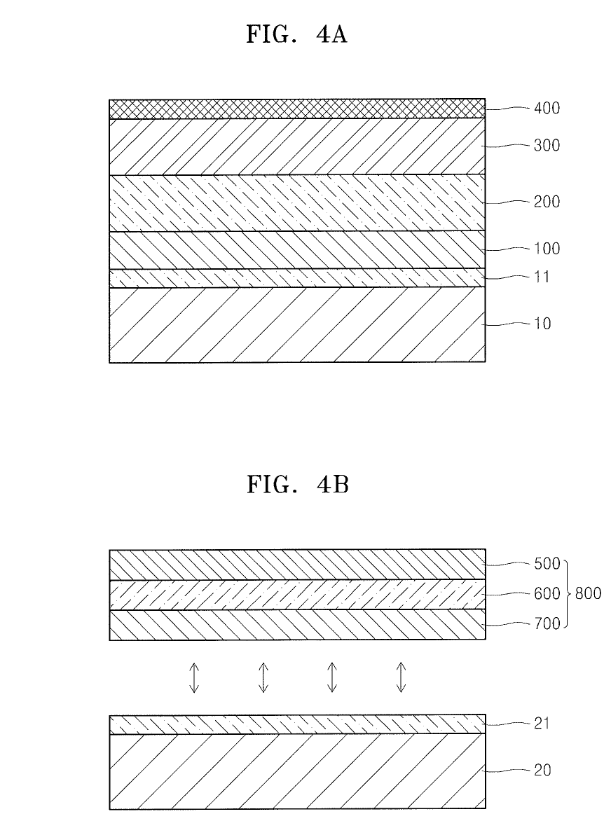

FIGS. 4A to 6 are cross-sectional views illustrating another embodiment of a method for manufacturing a flexible display apparatus.

Referring to FIG. 4A, the first flexible substrate 100 is formed on the first sacrificial layer 11 on the first support substrate 10. The first support substrate 10 may include a glass material, a metallic material, or other materials having a sufficient solidity. The first flexible substrate 100 has a flexible characteristic, and the first support substrate 10 supports the first flexible substrate 100 along with one or more additional layers.

The first sacrificial layer 11 may be first formed on the first support substrate 10 before forming the first flexible substrate 100. The first sacrificial layer 11 may include a-Si, a metallic material, an organic material such as polyimide, or other materials. The first sacrificial layer 11 may protect the first flexible substrate 100 and allow detachment of the first flexible substrate 100 from the first support substrate 10 to be easily performed.

The first flexible substrate 100 has a flexible characteristic and may include a metallic material, a plastic material such as PET, PEN, or polyimide, and/or or other materials. In one embodiment, a thin metal foil such as SUS may be used.

Thereafter, the display layer 200 may be formed on the first flexible substrate 100. The display layer 200 may include, for example, a thin-film transistor TFT, a capacitor CAP, and an organic light-emitting device electrically connected to the TFT. The organic light-emitting device may have a predetermined number of sub-pixels, e.g., of R, G, and B sub-pixels and or other combinations of colors or white.

The thin-film encapsulation layer 300 is formed on the display layer 200. The thin-film encapsulation layer 300 may be formed, for example, by alternately stacking inorganic and organic layers. Because the organic light-emitting device is formed of an organic material, the organic light-emitting device may be weak under various environmental or external conditions, e.g., oxygen, humidity, etc. Thus, the thin-film encapsulation layer 300 may be formed to have a multi-layer structure on the organic light-emitting device, in order to protect the organic light-emitting device from the environmental or external conditions (e.g., oxygen and/or humidity permeated from the outside).

The adhesive layer 400 may be formed on the thin-film encapsulation layer 300. The adhesive layer 400 functions to bond the color filter layer 500 and the thin-film encapsulation layer 300. FIG. 4A illustrates that the adhesive layer 400 is formed on the thin-film encapsulation layer 300. In another embodiment, the adhesive layer 400 may be formed on the color filter layer 500. The adhesive layer 400 may include silicon or another material.

Referring to FIG. 4B, an upper panel unit 800 including the second flexible substrate 700, the touch screen layer 600 formed on the second flexible substrate 700, and the color filter layer 500 formed on the touch screen layer 600 is formed on the second support substrate 20. For example, in order to form the upper panel unit 800, the second flexible substrate 700 is first formed on the second sacrificial layer 21 on the second support substrate 20. The second support substrate 20 may include a glass material, a metallic material. and/or other materials having a predetermined solidness. The second flexible substrate 700 has a flexible characteristic, and the second support substrate 20 supports the second flexible substrate 700 along with one or more additional layers.

The second sacrificial layer 21 may be first formed on the second support substrate 20 before forming the second flexible substrate 700. The second sacrificial layer 21 may include a-Si, a metallic material, an organic material such as polyimide, or other materials. The second sacrificial layer 21 may protect the second flexible substrate 700 and allow detachment of the second flexible substrate 700 from the second support substrate 20 to be easily performed. The second flexible substrate 700 may have the same flexible characteristic as the first flexible substrate 100 and may include the same material as the first flexible substrate 100.

Thereafter, the touch screen layer 600 may be formed on the second flexible substrate 700. The touch screen layer 600 may include a touch sensor. The touch sensor may include a first electrode and a second electrode which are alternately disposed and which have a hexagonal shape, diamond shape, or other shape. The touch sensor may be a capacitive touch sensor, e.g., one that determines a touch by detecting a change in capacitance at one or more of a plurality of first electrodes and second electrodes.

The color filter layer 500 may be formed on the touch screen layer 600. The color filter layer 500 includes the color filters 510R, 510G, and 510B and the light-blocking layer 520 disposed between the color filters 510R, 510G, and 510B. In detail, the color filters 510R, 510G, and 510B are formed for the sub-pixels of R, G. and B, respectively, and the light-blocking layer 520 may be formed between the color filters 510R, 510G, and 510B formed for the respective sub-pixels to prevent light emitted by the sub-pixels of R, G, and B from being leaked to an adjacent sub-pixel.

Thereafter, as shown in FIG. 4B, the upper panel unit 800 may be detached from the second support substrate by performing a delaminating operation between the second sacrificial layer 21 and the upper panel unit 800. For example, when the second sacrificial layer 21 includes a-Si, the second support substrate 20 may be detached by irradiating a laser beam. The laser may be, for example, an excimer laser, a solid-state laser, or a pulse laser. Another detachment method may be used, for example, depending on the materials of the second sacrificial layer 21.

After detaching the second support substrate 20, an upper protective film may be attached to the surface of the second flexible substrate 700, in order to protect the second flexible substrate 700 from an external impact, impurities, and the like.

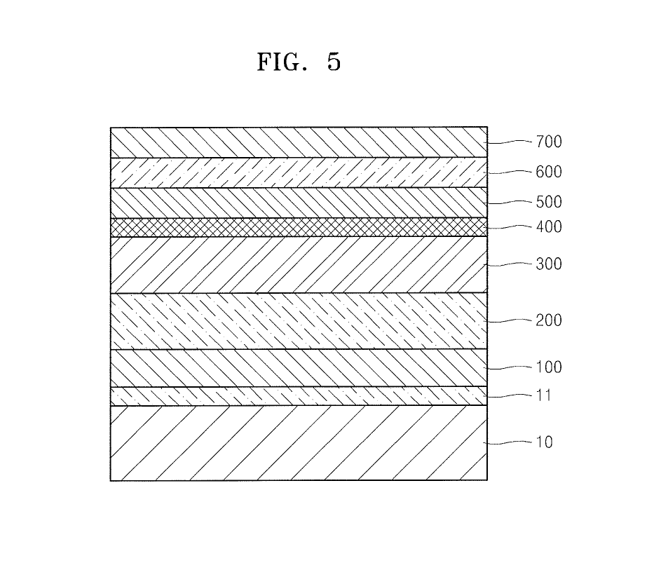

Thereafter, referring to FIG. 5, the first support substrate 10 and the upper panel unit 800 may be bonded, with the adhesive layer 400 between the thin-film encapsulation layer 300 and the upper panel unit 800. For example, the thin-film encapsulation layer 300 and the color filter layer 500 of the upper panel unit 800 are disposed to face each other with the adhesive layer 400 therebetween. In one embodiment, the following layers may be sequentially arranged: the first flexible substrate 100, the display layer 200, the thin-film encapsulation layer 300, the adhesive layer 400, the color filter layer 500. the touch screen layer 600. and the second flexible substrate 700 are sequentially disposed on the first support substrate 10. In one embodiment, the first sacrificial layer 11 may be between the first support substrate 10 and the first flexible substrate 100.

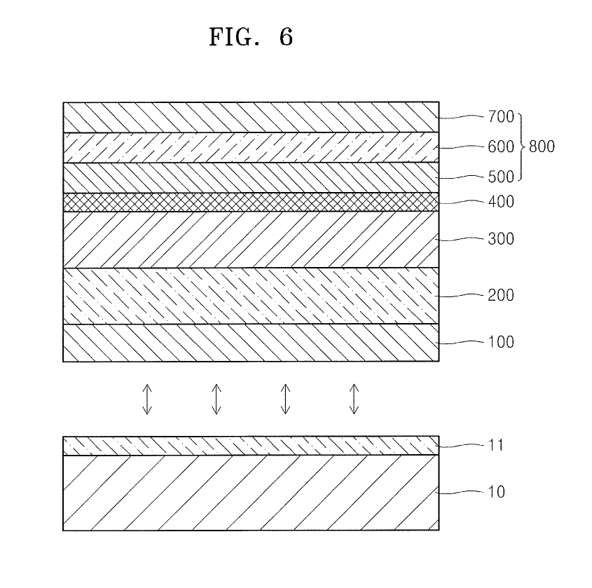

Thereafter, referring to FIG. 6, the first support substrate 10 may be detached by performing a delaminating operation between the first sacrificial layer 11 and the first flexible substrate 100. For example, when the first sacrificial layer 11 includes a-Si, the first support substrate 10 may be detached by irradiating a laser beam thereon. The laser may be, for example, an excimer laser, a solid-state laser, or a pulse laser. In another embodiment, a different detachment method may be used, for example, depending on the materials of the first sacrificial layer 11.

After detaching the first support substrate 10, a lower protective film may be attached to the surface of the first flexible substrate 100, in order to protect the first flexible substrate 100 from an external impact, impurities, and the like.

This method embodiment, therefore, includes a process of forming the touch screen layer 600 and the color filter layer 500 on the second flexible substrate 700 as one body, detaching the one body from the second support layer 20, and bonding the one body to the thin-film encapsulation layer 300. As a result, light-extraction efficiency may be improved through the color filters 510R, 510G, and 510B formed for respective sub-pixels without using a polarizer. Also, a TSP may be simultaneously formed through the touch screen layer 600 in one body with the color filter layer 500, without performing a separate module process. Thus, the total process may be simplified and manufacturing costs may be significantly reduced.

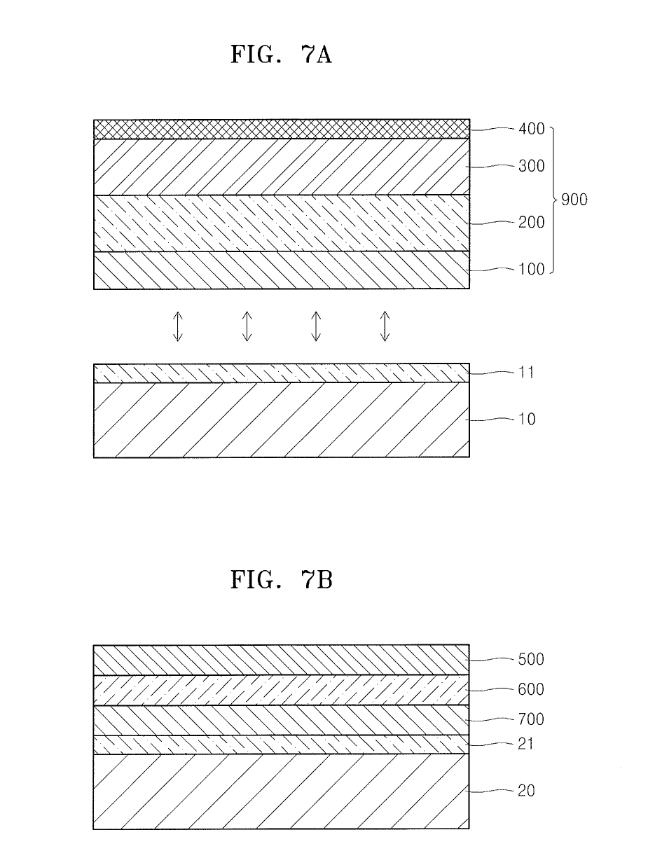

FIGS. 7A to 9 are cross-sectional views illustrating another embodiment of a method of manufacturing a flexible display apparatus.

Referring to FIG. 7A, a lower panel unit 900 is formed on the first support substrate 10. The forming the lower panel unit 900 may include forming the first flexible substrate 100 on the first sacrificial layer 11 on the first support substrate 10, forming the display layer 200 including a thin-film transistor TFT and an organic light-emitting device electrically connected to the thin-film transistor TFT, on the first flexible substrate 100, and forming the thin-film encapsulation layer 300 by alternately stacking organic and inorganic layers on the display layer 200.

For example, the first flexible substrate 100 is first formed on the first sacrificial layer 11 on the first support substrate 10. The first support substrate 10 may include a glass material, a metallic material, and/or other materials having a predetermined solidness. The first flexible substrate 100 has a flexible characteristic, and the first support substrate 10 supports the first flexible substrate 100 along with one or more additional layers.

The first sacrificial layer 11 may be first formed on the first support substrate 10 before forming the first flexible substrate 100. The first sacrificial layer 11 may include a-Si, a metallic material, an organic material such as polyimide, and/or other materials. The first sacrificial layer 11 may protect the first flexible substrate 100 and allow an operation for detaching the first flexible substrate 100 from the first support substrate 10 to be more easily performed.

The first flexible substrate 100 has a flexible characteristic and may include a metallic material, a plastic material such as PET, PEN, polyimide, and/or other materials. In accordance with one embodiment, a thin metal foil such as SUS may be used.

Thereafter, the display layer 200 may be formed on the first flexible substrate 100. The display layer 200 may include, for example, a thin-film transistor TFT, a capacitor CAP, and an organic light-emitting device electrically connected to the TFT. The organic light-emitting device may have a predetermined number of sub-pixels, e.g., R, G, and B sub-pixels and/or a combination of other color sub-pixels or white.

The thin-film encapsulation layer 300 is formed on the display layer 200. The thin-film encapsulation layer 300 may be formed by alternately stacking inorganic and organic layers. Because the organic light-emitting device is formed of an organic material, the organic light-emitting device may be weak under certain environmental or external conditions, (e.g., oxygen, humidity, etc). Thus, the thin-film encapsulation layer 300 may be formed to have a multi-layer structure on the organic light-emitting device, in order to protect the organic light-emitting device from the environmental or external conditions (e.g., oxygen and humidity permeated from the outside).

The adhesive layer 400 may be formed on the thin-film encapsulation layer 300. The adhesive layer 400 functions to bond the color filter layer 500 and the thin-film encapsulation layer 300. FIG. 7A illustrates that the adhesive layer 400 is formed on the thin-film encapsulation layer 300. In another embodiment, the adhesive layer 400 may be formed on the color filter layer 500. The adhesive layer 400 may include silicon or other materials.

Thereafter, as illustrated in FIG. 7A, the lower panel unit 900 may be detached from the first support substrate 10 by performing a delaminating operation between the first sacrificial layer 11 and the lower panel unit 900. For example, when the first sacrificial layer 11 includes a-Si, the first support substrate 10 may be detached by irradiating a laser beam thereon. The laser may be, for example, an excimer laser, a solid-state laser, or a pulse laser. In another embodiment, another detachment operation may be performed based on materials of the first sacrificial layer 11.

After detaching the first support substrate 10, a lower protective film may be attached to the surface of the first flexible substrate 100, in order to protect the first flexible substrate 100 from an external impact, impurities, and the like.

Referring to FIG. 7B, the second flexible substrate 700 is formed on the second sacrificial layer 21 on the second support substrate 20. The second support substrate 20 includes a glass material, a metallic material, and/or other materials having a predetermined solidness. The second flexible substrate 700 has a flexible characteristic, and the second support substrate 20 supports the second flexible substrate 700 in addition to one or more other layers.

The second sacrificial layer 21 may be first formed on the second support substrate 20 before forming the second flexible substrate 700. The second sacrificial layer 21 may include a-Si, a metallic material, an organic material such as polyimide, and/or other materials. The second sacrificial layer 21 may protect the second flexible substrate 700 and allow the second flexible substrate 700 to be more easily detached from the second support substrate 20. The second flexible substrate 700 may have the same flexible characteristic as the first flexible substrate 100 and may include the same material as the first flexible substrate 100.

Thereafter, the touch screen layer 600 may be formed on the second flexible substrate 700. The touch screen layer 600 may include a touch sensor. The touch sensor may include a first electrode and a second electrode which are alternately disposed and may have a hexagonal shape, diamond shape, or other shapes. The touch sensor may be a capacitive touch sensor, e.g., one which determines a touch by detecting a change in a capacitance in one or more of a plurality of first electrodes and second electrodes.

The color filter layer 500 may be formed on the touch screen layer 600. The color filter layer 500 may include a predetermined number of color filters (e.g., 510R, 510G, and 510B) and the light-blocking layer 520 disposed between the color filters 510R, 510G, and 510B. For example, the color filters 510R, 510G, and 510B are formed for the sub-pixels of R, G, and B, respectively. The light-blocking layer 520 may be formed between the color filters 510R, 510G, and 510B formed for the respective sub-pixels to prevent light emitted by the sub-pixels of R, G, and B from leaking to an adjacent sub-pixel.

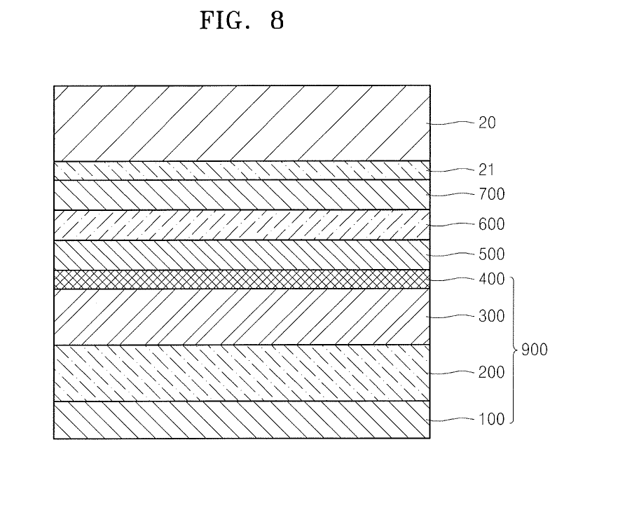

Thereafter, referring to FIG. 8, the second support substrate 20 and the lower panel unit 900 may be bonded, with the adhesive layer 400 interposed between the lower panel unit 900 and the color filter layer 500. For example, the thin-film encapsulation layer 300 of the lower panel unit 900 and the color filter layer 500 are disposed to face each other. with the adhesive layer 400 interposed therebetween. In one embodiment. the following layers may be sequentially arranged: display layer 200, the thin-film encapsulation layer 300, the adhesive layer 400, the color filter layer 500, the touch screen layer 600, the second flexible substrate 700, and the second support substrate 20 are sequentially disposed on the first flexible substrate 100. In one embodiment, the second sacrificial layer 21 may be between the second support substrate 20 and the second flexible substrate.

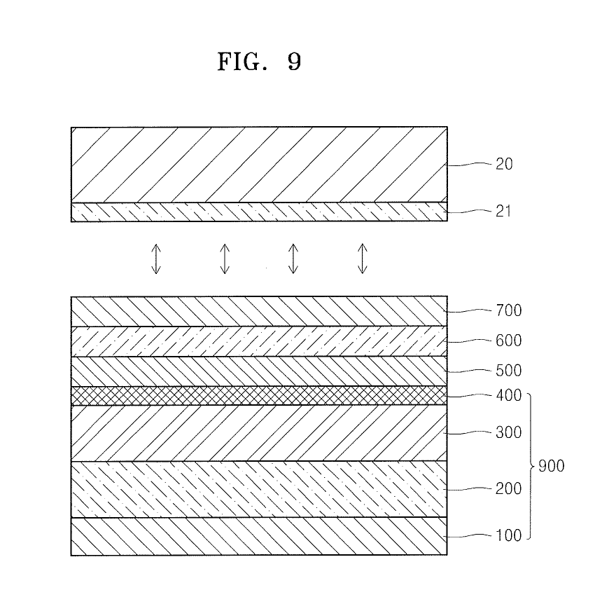

Thereafter, referring to FIG. 9, the second support substrate 20 may be detached by performing a delaminating operation between the second sacrificial layer 21 and the second flexible substrate 700. For example, when the second sacrificial layer 21 includes a-Si, the second support substrate 20 may be detached by irradiating a laser beam thereon. The laser may be, for example, an excimer laser, a solid-state laser, or a pulse laser. In another embodiment, a different detachment operation may be performed, for example, depending on materials of the second sacrificial layer 21.

After detaching the second support substrate 20, an upper protective film may be attached to the surface of the second flexible substrate 700, in order to protect the second flexible substrate 700 from an external impact, impurities, and the like.

The present embodiment, therefore, includes a process of forming the touch screen layer 600 and the color filter layer 500 on the second flexible substrate 700 as one body, detaching the one body from the second support layer 20, and bonding the one body to the thin-film encapsulation layer 300. As a result, light-extraction efficiency may be improved through the color filters 510R, 510G, and 510B formed for respective sub-pixels without using a polarizer. Also, TSP may be simultaneously formed through the touch screen layer 600 in one body with the color filter layer 500 without performing a separate module process. Thus, the total process may be simplified and manufacturing costs may be significantly reduced.

In accordance with another embodiment, a flexible display apparatus may be manufactured using any of the aforementioned method embodiments.

FIG. 10 is a cross-sectional view illustrating another embodiment of a flexible display apparatus. Referring to FIG. 10, the flexible display apparatus includes the first flexible substrate 100, the display layer 200 including an organic light-emitting device, the thin-film encapsulation layer 300 having a multi-structure, the adhesive layer 400 disposed on the thin-film encapsulation layer 300, and the color filter layer 500, the touch screen layer 600, and the second flexible substrate 700 which are formed in one body.

The first flexible substrate 100 has a flexible characteristic and may include a metallic material, a plastic material, such as PET, PEN, or polyimide, and/or other materials. In one embodiment, a thin metal foil such as SUS may be used.

The display layer 200 is disposed on the first flexible substrate 100. The display layer 200 may include, for example, a thin-film transistor TFT, a capacitor CAP, and an organic light-emitting device electrically connected to the TFT. The TFT may include, for example, a gate electrode 140, a source electrode 160, a drain electrode 162, and a semiconductor layer 120 including a-Si, polycrystalline silicon, or an organic semiconductor material. A method for forming the flexible display apparatus of FIG. 10 will now be described.

First, a buffer layer 110 (including, for example, silicon oxide or silicon nitride) is disposed on the first flexible substrate 100. The buffer layer 110 serves to planarize the surface of the first flexible substrate 100 and/or prevent impurities or the like from permeating the semiconductor layer 120 of the thin-film transistor TFT. The semiconductor layer 120 may be disposed on the buffer layer 110.

The gate electrode 140 is disposed on the semiconductor layer 120. The source electrode 160 and the drain electrode 162 are electrically conducted according to a signal applied to the gate electrode 140. The gate electrode 140 may be formed in a single layer or multiple layers, and, for example, may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The materials used to form the gate electrode may be selected, for example, by taking any of the following into consideration: adherence to an adjacent layer, surface planarization of a layer on which the gate electrode 140 is to be stacked, working properties, and the like.

To secure the insulation property between the semiconductor layer 120 and the gate electrode 140, a gate insulating layer 130 (including, for example, silicon oxide or silicon nitride) may be interposed between the semiconductor layer 120 and the gate electrode 140.

An interlayer insulating layer 150 may be disposed on the gate electrode 140. The interlayer insulating layer 150 may be include, for example. silicon oxide or silicon nitride. and may be formed in a single layer or multiple layers.

The source electrode 160 and the drain electrode 162 are disposed on the interlayer insulating layer 150. Each of the source electrode 160 and the drain electrode 162 is electrically connected to the semiconductor layer 120 through a contact hole in the interlayer insulating layer 150 and the gate insulating layer 130. The source electrode 160 and the drain electrode 162 may have a single-layer or multiple-layer structure, and may include materials such as, for example, Al, Pt, Pd, Ag, Mg, Au, Ni, Nd, Ir, Cr, Li, Ca, Mo, Ti, W, and/or Cu. The materials may be selected by taking conductivity and/or other properties into consideration.

A protective layer covering the thin-film transistor TFT may be disposed to protect the thin-film transistor TFT having the structure described above. The protective layer may include, for example, an inorganic material, for example, silicon oxide, silicon nitride, silicon oxynitride, or the like.

A first insulating layer 170 may be disposed on the first flexible substrate 100. In this case, the first insulating layer 170 may be a planarization layer or a protective layer. The first insulating layer 170 functions to planarize the upper surface of the thin-film transistor TFT and to protect the thin-film transistor TFT and various other devices when an organic light-emitting device is disposed on the thin-film transistor TFT. The first insulating layer 170 may be formed, for example, of an acrylic organic material, benzocyclobutene (BCB), or the like. As shown in FIG. 10, the buffer layer 110, the gate insulating layer 130, the interlayer insulating layer 150. and the first insulating layer 170 may be formed on the whole surface of the first flexible substrate 100.

A second insulating layer 180 may be disposed on the thin-film transistor TFT. In this case, the second insulating layer 180 may be a pixel defining layer. The second insulating layer 180 may be located on the first insulating layer 170 described above and may have an opening. The second insulating layer 180 functions to define pixel areas on the first flexible substrate 100.

The second insulating layer 180 may include, for example, an organic insulating layer. The organic insulating layer may include, for example, an acrylic polymer such as polymethylmethacrylate (PMMA), polystyrene (PS), polymer derivatives having a phenol group, imide-group polymer, arylether-group polymer, amide-group polymer, fluorine-group polymer, p-xylene-group polymer, vinyl alcohol group polymer, a combination thereof.

Organic light-emitting devices (e.g., a red sub-pixel 250R, a green sub-pixel 250G, and a blue sub-pixel 250B) may be disposed on the second insulating layer 180. The red sub-pixel 250R emits red light and may include a pixel electrode 210R, an intermediate layer 220R, and an opposite electrode 230. The green sub-pixel 250G emits green light and may include a pixel electrode 210G, an intermediate layer 220G, and the opposite electrode 230. The blue sub-pixel 250B emits blue light and may include a pixel electrode 210B, an intermediate layer 220B, and the opposite electrode 230. In this case, the opposite electrode 230 may be disposed on the whole surface of the first flexible substrate 100.

The pixel electrodes 210R, 201G and 210B may be, for example, a transparent (or translucent) electrode or a reflective electrode. When the pixel electrodes 2108, 201G, and 210B are transparent (or translucent) electrodes, the pixel electrodes 210R, 201G, and 210B may include, for example, indium tin oxide (ITO), indium zinc oxide (IZO), zinc oxide (ZnO), indium oxide (In₂O₃), indium gallium oxide (IGO), and/or aluminum zinc oxide (AZO). When the pixel electrodes 210R, 201G, and 210B are reflective electrodes, the pixel electrodes 210R, 201G, and 210B may include a reflective layer containing, for example, Ag, Mg, Al, Pt, Pd, Au, Ni, Nd, Ir, Cr, or a compound thereof, and a layer including ITO, IZO, ZnO, In₂O₃, IGO, and/or AZO. In another embodiment, the pixel electrodes 210R, 201G, and 210B may be formed of other materials. Also, the pixel electrodes 210R, 201G, and 210B may have a single-layer or a multi-layer structure.

In the pixel areas defined by the second insulating layer 180, the intermediate layer 220R for red emission, the intermediate layer 220G for green emission, and the intermediate layer 220B for blue emission may be respectively disposed for the red sub-pixel 250R, the green sub-pixel 250G, and the blue sub-pixel 250B. The intermediate layers 220R, 220G, and 220B include emission layers (EMLs) for emitting red light, green light, and blue light, respectively, and besides the EMLs, each of the intermediate layers 220R, 220G, and 220B may include a hole injection layer (HIL), disposed between the EML and the pixel electrode 210R, 210G, or 210B, a hole transport layer (HTL). an electron transport layer (ETL) disposed between the EML and the opposite electrode 230, an electron injection layer (EIL), and the like which are stacked and formed in a single or complex structure. In other embodiments. the intermediate layers 220R. 2200, and 220B may have different structures.

The opposite electrode 230 covers the intermediate layers 220R, 220G, and 220B including the EMLs, and faces the pixel electrodes 210R, 210G, and 210B. The opposite electrodes 230 may be disposed, for example, on the whole surface of the first flexible substrate 100. The opposite electrode 230 may be a transparent (or translucent) electrode or a reflective electrode.

When the opposite electrode 230 is formed as a transparent (or translucent) electrode, the opposite electrode 230 may have a layer including a metal having a low work function (e.g., Li, Ca, lithium fluoride (LiF)/Al, Al, Ag, Mg, or a compound thereof), and a transparent (or translucent) conductive layer including ITO, IZO, ZnO, and/or In₂O₃. In another embodiment, the opposite electrode 230 may be a different type and/or may have a different structure or material.

Referring to FIG. 10, the thin-film encapsulation layer 300 may be disposed on the first flexible substrate 100 to cover the display layer 200. The thin-film encapsulation layer 300 may have a multi-layer structure in which organic layers 310 and 330 and inorganic layers 320 and 340 are stacked. The thin-film encapsulation layer 300 may have a multi-layer structure to prevent a display unit from being damaged by oxygen, humidity, and/or other environmental or external influences.

The organic layers 310 and 330 may include. for example, an acrylic resin, methacrylic resin, polyisoprene, vinyl-group resin, epoxy-group resin, urethane-group resin, cellulose-group resin, and/or parylene-group resin. In addition, the inorganic layers 320 and 340 may include, for example, silicon nitride. aluminum nitride, zirconium nitride. titanium nitride, hafnium nitride. tantalum nitride. silicon oxide, aluminum oxide, titanium oxide, tin oxide, cerium oxide, and/or silicon oxynitride (SiON). Although FIG. 10 shows that the organic layers 310 and 330 and the inorganic layers 320 and 340 have dual-layer structure, but these layers may have a different structure in other embodiments.

The upper panel unit 800 formed in one body may be disposed on the thin-film encapsulation layer 300. The upper panel unit 800 may include the color filter layer 500, the touch screen layer 600, and the second flexible substrate which are sequentially disposed. The adhesive layer 400 is between the upper panel unit 800 and the thin-film encapsulation layer 300, and functions to attach the upper panel unit 800 to the thin-film encapsulation layer 300. The adhesive layer 400 may include, for example, silicon and/or another material.

The color filter layer 500 may include the color filters 510R, 510G, and 510B disposed for respective sub-pixels and the light-blocking layer 520 disposed between the color filters 510R, 510G, and 510B. The color filter layer 500 is a colored layer for passing light of a specific wavelength band. For example, the red color filter 510R for passes light of a red wavelength band, the green color filter 510G passes light of a green wavelength band, and the blue color filter 510B passes light of a blue wavelength band. Each of the color filters 510R, 510G, and 510B may used a variety of materials to achieve these purpose and may be disposed at corresponding locations for each sub-pixel, for example, by an etching method which uses a printing method, an inkjet method, or a photolithography method.

The light-blocking layer 520 may be disposed between the color filters 510R, 510G, and 510B. The light-blocking layer 520 blocks light incident from an adjacent sub-pixel and limits a mixed color between adjacent sub-pixels. The light-blocking layer 520 may include, for example, a metal, organic resin, or other materials.

The touch screen layer 600 may be disposed on the color filter layer 500. The color filter layer 500 is disposed on one surface of the touch screen layer 600, and the second flexible substrate 700 is disposed on the other surface of the touch screen layer 600, to thereby form one body. The second flexible substrate 700 may include the same material as the first flexible substrate 100. An upper protective layer may be disposed on the second flexible substrate 700.

The touch screen layer 600 may include a touch sensor having a first electrode and a second electrode, which are alternately disposed and which have a hexagonal shape, diamond shape, or another shape. For example, the touch sensor may be a capacitive touch sensor, e.g., one which determines a touch by detecting a change in a capacitance at one or more of a plurality of first electrodes and second electrodes. An insulating layer, an adhesive layer, and the like, may be interposed between the color filter layer 500 and the one surface of the touch screen layer 600, and between the touch screen layer 600 and the other surface of the touch screen layer 600.

The embodiment, therefore, includes a process of forming the touch screen layer 600 and the color filter layer 500 on the second flexible substrate 700 as one body, detaching the one body from the second support layer 20, and bonding the one body to the thin-film encapsulation layer 300. As a result, light-extraction efficiency may be improved through the color filters 510R. 510G. and 510B formed for respective sub-pixels without using a polarizer. Also. a TSP may be simultaneously formed through the touch screen layer 600 formed in one body with the color filter layer 500 without a separate module process. Thus, a total process may be simplified and manufacturing costs may be significantly reduced.

By way of summation and review, recently, flexible organic light-emitting displays have been developed. These displays have a flexible substrate, a polarizer, and a touch screen panel. The flexible substrate is made of a resin instead of glass. Also, manufacturing costs increases due to the polarizer, and a manufacturing process is complicated because the touch screen panel is applied in a module process, which is another cause for increasing manufacturing costs. In accordance with one or more of the aforementioned embodiments, a flexible display apparatus is provided which does no user a polarizer. Also, a manufacturing process is simplified and optical characteristics are improved.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features. characteristics. and/or elements described in connection with other embodiments unless otherwise indicated. Accordingly, it will be understood by those of skill in the art that various changes in form and details may be made without departing from the spirit and scope of the present invention as set forth in the following claims.

What is claimed is:

1. A method of manufacturing a flexible display apparatus, the method comprising:
forming a first flexible substrate on a first sacrificial layer on a first support substrate;
forming, on the first flexible substrate, a display layer including a thin-film transistor and an organic light-emitting device electrically connected to the thin-film transistor;
forming a thin-film encapsulation layer on the display layer by alternately stacking organic and inorganic layers;
forming a second flexible substrate on a second sacrificial layer on a second support substrate;
forming a touch screen layer on the second flexible substrate;
forming, on the touch screen layer, a color filter layer including color filters and a light-blocking layer between adjacent ones of the color filters;
bonding the first support substrate and the second support substrate based on an adhesive layer between the thin-film encapsulation layer and the color filter layer; and
detaching the first support substrate and the second support substrate by performing a delaminating operation between the first sacrificial layer and the first flexible substrate and between the second sacrificial layer and the second flexible substrate.

2. The method as claimed in 1, wherein each of the first flexible substrate and the second flexible substrate include a metallic material or a plastic material.

3. The method as claimed in 1, wherein detaching the first support substrate and detaching the second support substrate are performed using a laser beam.

4. A method of manufacturing a flexible display apparatus, the method comprising:
forming a first flexible substrate on a first sacrificial layer on a first support substrate;
forming, on the first flexible substrate, a display layer including a thin-film transistor and an organic light-emitting device electrically connected to the thin-film transistor;
forming a thin-film encapsulation layer on the display layer by alternately stacking organic and inorganic layers;
forming, on a second sacrificial layer on a second support substrate, an upper panel unit including a second flexible substrate, a touch screen layer on the second flexible substrate, and a color filter layer including color filters and a light-blocking layer between adjacent ones of the color filters on the touch screen layer;
detaching the upper panel unit from the second support substrate by performing a delaminating between the second sacrificial layer and the upper panel unit; bonding the first support substrate and the upper panel unit based on an adhesive layer between the thin-film encapsulation layer and the upper panel unit; and
detaching the first support substrate by performing a delaminating operation between the first sacrificial layer and the first flexible substrate.

5. The method as claimed in 4, wherein each of the first flexible substrate and the second flexible substrate include a metallic material or a plastic material.

6. The method as claimed in 4, wherein detaching the first support substrate and detaching the second support substrate are performed using a laser beam.

7. A method of manufacturing a flexible display apparatus, the method comprising:
forming a lower panel unit by forming a first flexible substrate on a first sacrificial layer on a first support substrate, forming, on the first flexible substrate, a display layer including a thin-film transistor and an organic light-emitting device electrically connected to the thin-film transistor, and forming a thin-film encapsulation layer on the display layer by alternately stacking organic and inorganic layers;
detaching the lower panel unit from the first support substrate by performing a delaminating operation between the first sacrificial layer and the first flexible substrate;
forming a second flexible substrate on a second sacrificial layer on a second support substrate;
forming a touch screen layer on the second flexible substrate;
forming, on the touch screen layer, a color filter layer including color filters and a light-blocking layer disposed between adjacent ones of the color filters;
bonding the lower panel unit and the second support substrate based on an adhesive layer between the thin-film encapsulation layer and the color filter layer; and
detaching the second support substrate by performing a delaminating operation between the second sacrificial layer and the second flexible substrate.

8. The method as claimed in 7, wherein each of the first flexible substrate and the second flexible substrate include a metallic material or a plastic material.

9. The method as claimed in 7, wherein detaching the first support substrate and detaching the second support substrate are performed using a laser beam.

10. A flexible display apparatus, comprising:
a first flexible substrate;
a display layer on the first flexible substrate and including an organic light-emitting device electrically connected to a thin-film transistor;
a thin-film encapsulation layer on the display layer and including a stack of alternating organic and inorganic layers;
a color filter layer on the thin-film encapsulation layer and including color filters and a light-blocking layer between adjacent ones of the color filters;
a touch screen layer on the color filter layer;
a second flexible substrate on the touch screen layer; and
an adhesive layer between the thin-film encapsulation layer and the color filter layer.

11. The apparatus as claimed in 10, wherein the color filter layer, the touch screen layer, and the second flexible substrate are in one body.

12. The apparatus as claimed in 11, wherein each of the first flexible substrate and the second flexible substrate include a metal or a plastic material.
